(19) United States
(12) Patent Application Publication
(10) Pub. No.: US 2025/0126755 A1
(43) Pub. Date: Apr. 17, 2025

(54) RECESSED HEAT SINK WITH A DISCERNIBLE COMPONENT AS PART OF A DEVICE ENCLOSURE

(71) Applicant: SK Hynix NAND Product Solutions Corp. (dba Solidigm), Rancho Cordova, CA (US)

(72) Inventors: Saad Bushnaq, Richmond (CA); Jaspal Bhachu, Delta (CA)

(21) Appl. No.: 18/380,431

(22) Filed: Oct. 16, 2023

(51) Int. Cl. H05K 7/20

(52) U.S. Cl. CPC H05K 7/20409; H05K 7/20436

(57) ABSTRACT

An enclosure, a related method for manufacturing thereof, and a device which includes thereof are disclosed herein. The enclosure includes a first outer surface and a second outer surface opposing the first outer surface. The enclosure further includes a heat sink arranged on the first outer surface, the heat sink including a plurality of protrusions extending outward from the first outer surface and a discernible component. The discernible component protrudes from the first outer surface and is recessed from the plurality of protrusions. The discernible component is distinguishable from the protrusions. The enclosure is to enclose circuitry between the first outer surface and the second outer surface, such that the circuitry is arranged closer to the second outer surface than to the first outer surface.

### TECHNICAL FIELD

The present disclosure is directed to a heat sink and more particularly to a finned-heat sink of an enclosure.

### SUMMARY

In accordance with the present disclosure, enclosures, methods for manufacturing thereof, and devices which include thereof are provided to reduce the amount of thermal interface material (TIM) needed within the enclosure and provide heat dissipation by use of a heat sink with a discernible component. The discernible component of the heat sink may be distinguishable and may appear as a recognizable image. For example, the discernible component may appear as a company logo to distinguish the enclosure from other housing used to enclose device circuitry. The enclosure may include a first outer surface, a second outer surface that opposes the first outer surface, and a heat sink which is arranged on the first outer surface to promote heat dissipation of the enclosure. The enclosure, methods for manufacturing thereof and device which includes thereof promote thermal transfer from heat-generating circuitry to the first outer surface and the second outer surface while reducing the amount of TIM disposed between the first outer surface and circuitry. The TIM is disposed in TIM layers, each of which is thermally conductive and arranged between the circuitry and the first outer surface and the second outer surface. The TIM layers are used to transfer heat generated from the circuitry to the first outer surface and the second outer surface. The heat sink arranged on the first outer surface includes a plurality of protrusions, each of the protrusions extending outward from the first outer surface, and a discernible component that protrudes from the first outer surface and is recessed from the plurality of protrusions. The discernible component of the heatsink is also distinguishable in appearance from the protrusions (e.g., the plurality of protrusions). In addition, the enclosure is formed to enclose circuitry between the first outer surface and the second outer surface and the circuitry is arranged closer to the second outer surface than to the first outer surface. The enclosure, the device which includes the enclosure and the methods disclosed herein are provided to reduce the amount of TIM material needed within the enclosure and provide a heat sink for thermal dissipation of the enclosure as well as a discernible component to present a distinguishable image.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIG. 1 shows a perspective diagram of an enclosure with a heat sink, in accordance with some embodiments of the present disclosure;

FIGS. 2A-2E shows an illustrative plan diagram and side view diagrams of the enclosure, in accordance with some embodiments of the present disclosure;

FIG. 3 shows an illustrative cross-sectional diagram of an enclosure with a heat sink, in accordance with some embodiments of the present disclosure;

FIG. 4 shows an illustrative diagram of a device which includes an enclosure that encloses circuitry, in accordance with some embodiments of the present disclosure; and

FIG. 5 shows a flowchart of illustrative steps for manufacturing an enclosure with a heat sink, in accordance with some embodiments of the present disclosure.

### DETAILED DESCRIPTION

In accordance with the present disclosure, enclosures, methods for manufacturing thereof and devices which include thereof are provided to reduce the amount of thermal interface material (TIM) needed within the enclosure and provide heat dissipation by use of a heat sink with a discernible component which may be used to appear as a recognizable image. In some embodiments, the first outer surface and the second outer surface form the enclosure which encloses circuitry disclosed herein. The enclosure disclosed herein may be any suitable housing used to enclose circuitry of any suitable form factor. In some embodiments, the enclosure and devices disclosed herein are of a standardized size and standardized dimensions. In some devices, electrical components mounted on circuitry have become smaller or thinner while the circuitry is arranged in enclosures of a standardized size to be fitted onto a rack or shelf. In such devices, more TIM is necessary to thermally couple the electrical components of the circuitry to the enclosure. The heat sink arranged on the first outer surface of the enclosure disclosed herein includes a recess or lowered surface in order to reduce the amount of TIM needed between the first outer surface and the circuitry. The recess or lowered surface of the heat sink also enables protrusions of the heat sink to be formed. In some embodiments, each of the protrusions of the heat sink may extend as far as the standardized size or dimensions permit. Reducing the amount of TIM disposed in the enclosure reduces the total cost of arranging the enclosures.

The recessed heat sink arranged in an enclosure of a standardized size and dimensions enables protrusions (e.g., fins or pins) to be formed within the heat sink to increase the amount of surface area, improving heat dissipation of the enclosure. The heat sink disclosed herein also includes a discernible component arranged among the protrusions of the heat sink, such that the discernible component is distinguishable from the protrusions of the heat sink. In some embodiments, the discernible component protrudes outward from the first outer surface, similarly to the protrusions. The discernible component included within the heat sink may be recessed from the protrusions and may be a visually distinctive or recognizable image (e.g., a company logo or symbol).

The circuitry is arranged between the first outer surface and the second outer surface, the circuitry including electrical components, at least one of which is a heat-generating electrical component. The heat-generating electrical component of circuitry may be any suitable high-performance electrical component (e.g., an integrated circuit device, such as a memory controller). In some embodiments, the circuitry includes a printed circuit board (PCB), which may include multiple dielectric layers, on which the electrical components may be mounted. In some embodiments, TIM layers may be positioned between the circuitry and each of the first outer surface and the second outer surface.

For purposes of brevity and clarity, the features of the disclosure described herein are in the context of an enclosure with a recessed heatsink. However, the principles of the present disclosure may be applied to any other suitable context in which an enclosure is used to enclose heat-generating circuitry.

In some embodiments, the circuitry of the device may include any suitable controller, which may include any suitable processing chip (e.g., an application-specific integrated circuit (ASIC) chip) or processing core.

In some embodiments, the device, enclosure and methods for manufacturing the enclosure of the present disclosure may include circuitry which functions as a storage device system (e.g., an SSD storage system), which includes a storage device such as a solid-state drive device.

An SSD is a data storage device that uses integrated circuit assemblies as memory to store data persistently. SSDs have no moving mechanical components, and this feature distinguishes SSDs from traditional electromechanical magnetic disks, such as hard disk drives (HDDs) or floppy disks, which contain spinning disks and movable read/write heads. Compared to electromechanical disks, SSDs are typically more resistant to physical shock, run silently, have lower access time, and less latency.

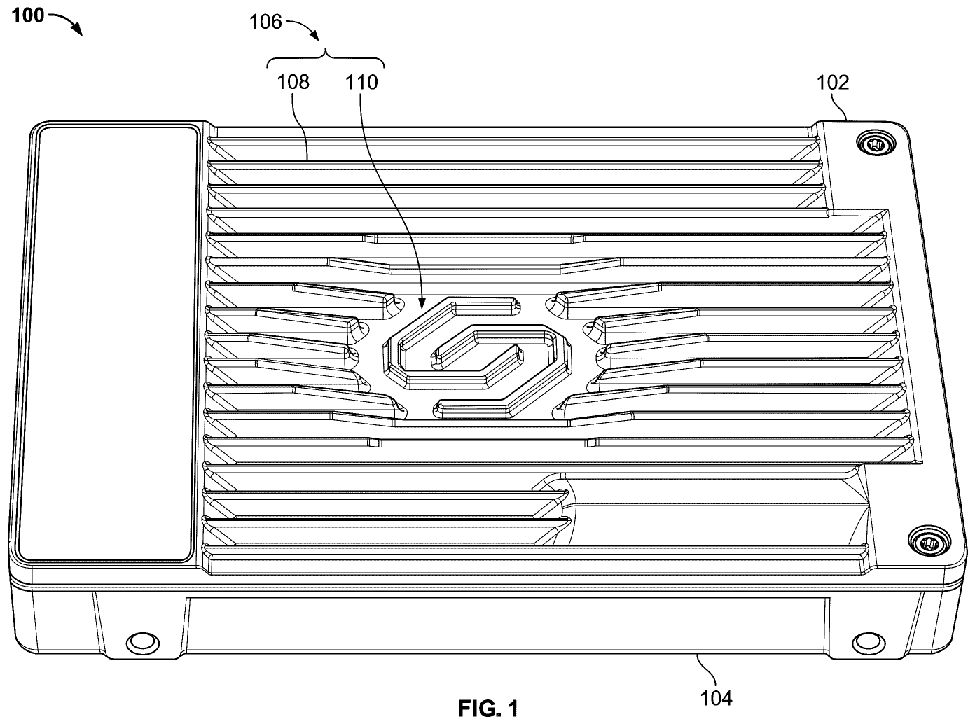

The subject matter of this disclosure may be better understood by reference to FIGS. 1-5.

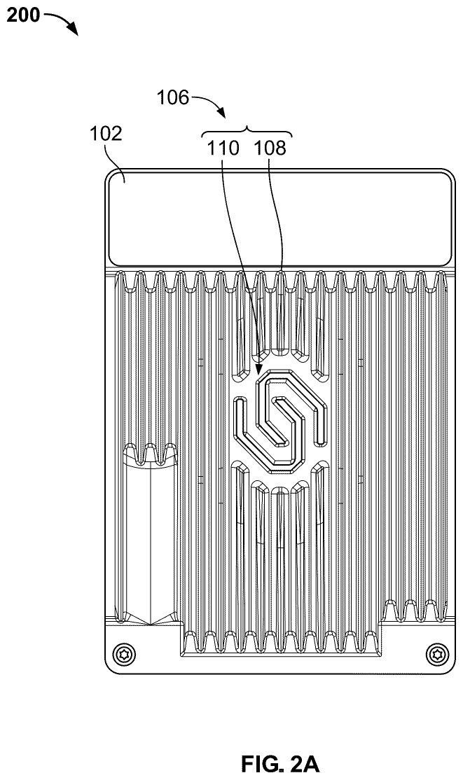

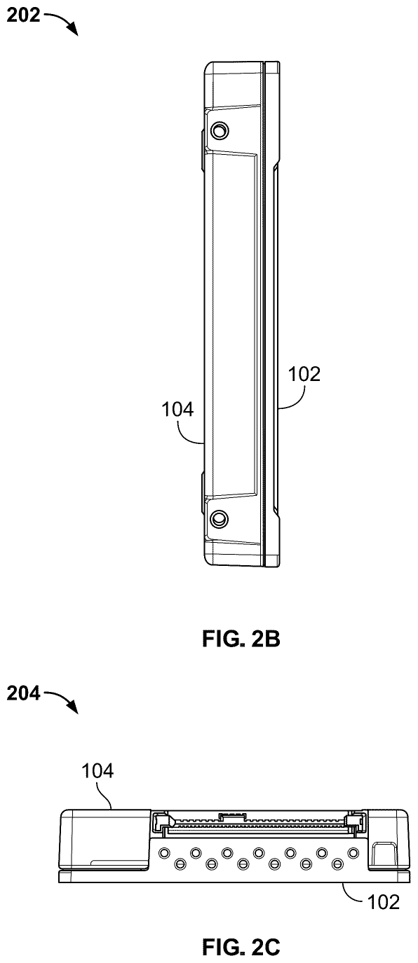

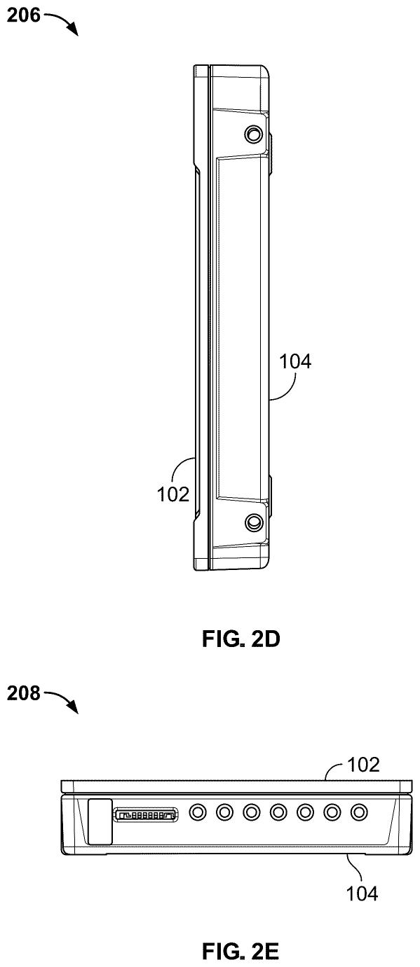

FIGS. 1 and 2A-2E show diagrams of an enclosure 100 with a heat sink 106 from different perspectives (e.g., perspective views 200, 202, 204, 206, and 208), in accordance with some embodiments of the present disclosure. The enclosure 100 includes a first outer surface 102, a second outer surface 104, and a heat sink 106 arranged on the first outer surface 102. The first outer surface 102 and the second outer surface 104 of the enclosure 100 are to enclose circuitry (not shown), which is arranged between the first outer surface 102 and the second outer surface 104.

FIG. 2A shows a top perspective view 200 of an enclosure (e.g., enclosure 100) with a heat sink 106. FIGS. 2B and 2D each show respective long side perspective views (e.g., left major-side perspective view 202, and right major-side perspective view 204) of enclosure 100 with the first outer surface 102 and second outer surface 104. FIGS. 2C and 2E each show respective short side perspective views (e.g., front minor-side perspective view 204 and back minor-side perspective view 208) of enclosure 100 with the first outer surface 102 and the second outer surface 104.

The first outer surface 102, which is opposite to the second outer surface 104, may include a recess in which a plurality of protrusions 108 are arranged. In some embodiments, the plurality of protrusions 108 of the heat sink 106 is one of a plurality of fins and a plurality of pins. In some embodiments, each respective protrusion of the plurality of protrusions 108 is parallel to each other protrusion. In some embodiments, each protrusion of the plurality of protrusions 108 is uniformly spaced from each other adjacent protrusion. In some embodiments, the plurality of protrusions 108 are non-uniformly spaced from each other adjacent protrusion. Although each of the protrusions 108 shown in FIGS. 1 and 2A is arranged parallel to each of the other adjacent protrusion 108, the plurality of protrusions 108 may be arranged in any suitable heat sink pattern (e.g., radially arranged protrusions, concentrically arranged protrusions). The enclosure 100 may be formed with first outer surface 102 such that the first outer surface 102 and the heat sink 106 are monolithic. In some embodiments, discernible component 110 of heat sink 106 appears as a recognizable image among the plurality of protrusions 108. In some embodiments, each of the first outer surface 102 and the second outer surface 104 is thermally conductive to dissipate heat generated from the circuitry when the circuitry is in operation.

In some embodiments, the circuitry includes a printed circuit board (PCB) with at least one electrical component, any respective one of which may generate heat while the circuitry is in operation. In some embodiments, the PCB includes multiple dielectric layers, on which at least one electrical component may be mounted. Any of the electrical components of the circuitry may be any suitable high-performance electrical component (e.g., an integrated circuit device, such as a memory controller).

It will be understood that, while enclosure 100 depict a particular embodiment of the enclosure with a certain size, shape, dimensions, orientation of protrusions 108 and a particular discernible component 110 of the heat sink 106 in accordance with the present disclosure, any other suitable enclosure may be implemented similarly. For example, an enclosure may include any suitable discernible component 110 within the heat sink 106 such that the discernible component 110 is distinguishable from the protrusions of the plurality of protrusions 108. In some embodiments, the discernible component 110 is recessed from the plurality of protrusions 108 and discernible component 110 is formed of a thermally conductive material. In some embodiments, the first outer surface 102 and heat sink 106, which includes the plurality of protrusions 108 and the discernible component 110, are monolithic.

For purposes of clarity and brevity, and not by way of limitation, the present disclosure is provided in the context of an enclosure 100, the manufacturing thereof, and a device that includes an enclosure 100 that provides the features and functionalities disclosed herein. The enclosure 100 may be at least partially implemented with, for example, a server device or storage device.

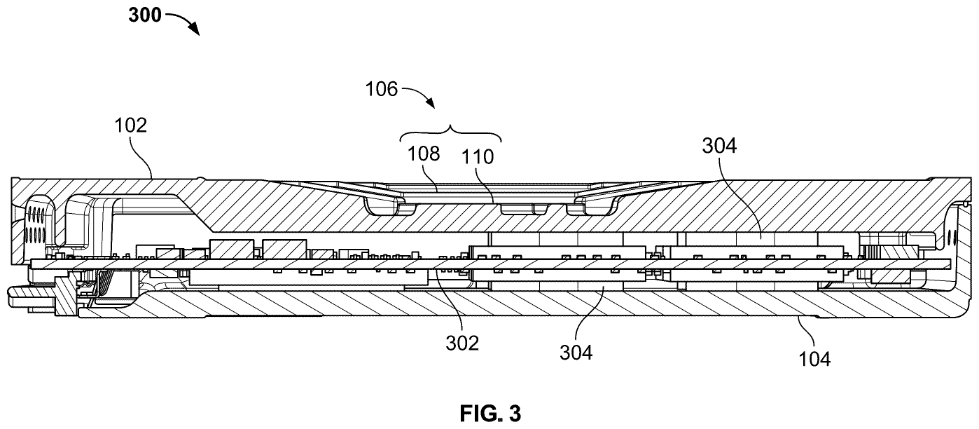

FIG. 3 shows an illustrative cross-sectional diagram of an enclosure 300 with a heat sink 106, in accordance with some embodiments of the present disclosure. Enclosure 300 includes a first outer surface 102 and a second outer surface 104 opposing the first outer surface 102, which are arranged to enclose circuitry 302. A heat sink 106 is arranged on the first outer surface 102, and the heat sink 106 includes a plurality of protrusions 108, each protrusion extending outward from the first outer surface 102. The plurality of protrusions 108 increases the total surface area of the first outer surface 102 from which heat generated by circuitry 302 is dissipated. The increase in total surface area promotes further heat dissipation from the first outer surface 102, reducing the likelihood of thermal throttling of electrical components of circuitry 302 or unsafe surface temperatures when handling or performing maintenance on enclosure 300. The heat sink 106 also includes a discernible component 110 which protrudes from the first outer surface, the discernible component 110 recessed from each of the plurality of protrusions 108 and distinguishable from the plurality of protrusions 108.

In some embodiments, the first outer surface 102, the second outer surface 104, or both are formed in any one of the following ways: die casting, molding or any other suitable process to form enclosure 300 with thermally-conductive material (e.g., aluminum). The first outer surface 102 and the second outer surface 104 are thermally conductive to dissipate heat generated from circuitry 302 which is to be enclosed within enclosure 300. In some embodiments, the enclosure is of standardized unit size (e.g., standardized dimensions) defined by a rack or shelf into or onto enclosure 300 is to be fitted. In such embodiments, the heat sink 106 of the first outer surface 102 includes a recess in the first outer surface 102 such that each of the plurality of protrusions 108 may only extend as far as the dimensions of the standardized unit size permits.

Enclosure 300 encloses circuitry 302 between the first outer surface 102 and the second outer surface 104. In some embodiments, the first outer surface 102 and the second outer surface 104 may be joined or physically coupled to form enclosure 300 in which circuitry 302 is to be enclosed and arranged. Circuitry 302 is to be enclosed within enclosure 300 for mechanical and electrical protection of circuitry 302 and to improve the thermal dissipation of heat generated by circuitry 302. The improved thermal dissipation reduces the likelihood of thermal throttling of any electrical components of circuitry 302. Circuitry 302 may include a printed circuit board (PCB) and at least one electrical component which generates heat during the operation of circuitry 302.

In some embodiments, the enclosure includes thermal interface material (TIM) layers 304, which is arranged between the circuitry 302 and each of the first outer surface 102 and the second outer surface 104, to promote efficient heat transfer from the circuitry to the thermally-conductive enclosure 300. In some embodiments, circuitry 302 is arranged closer to the second outer surface 104 than to the first outer surface 102. In some embodiments, the recess of the first outer surface 102 ensures that less TIM within TIM layer 304 is needed to transfer heat from circuitry 302 to the first outer surface 102 than a first outer surface 102 without a recess within which the protrusions 108 are arranged. In some embodiments, the recess of the first outer surface 102 also enables the heat sink 106 to be formed within a standardized unit size of enclosure 300. In some embodiments, the TIM layer 304 disposed between the first outer surface 102 and circuitry 302 includes a first amount of TIM disposed between the recess of the first outer surface 102 and circuitry 302 and a second amount of TIM disposed between a non-recessed portion of the first outer surface 102 and circuitry 302 and the first amount of TIM is less than the second amount of TIM. The reduced amount of TIM material for TIM layers 304 reduces the overall cost of enclosure 300 and related devices that include thereof. In some embodiments, TIM layers 304 may be of any suitable thermally-conductive material to promote heat transfer from circuitry 302 to each of the first outer surface 102 and the second outer surface 104. Each of the TIM layers 304 is disposed in thermal contact with circuitry 302 and each of the first outer surface 102 and the second outer surface 104, respectively.

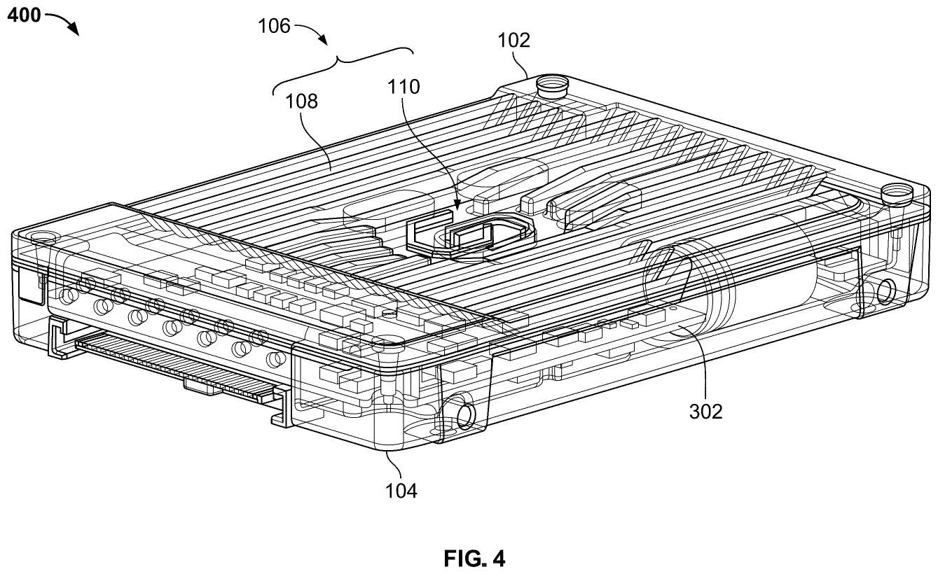

FIG. 4 shows an illustrative diagram of a device 400 which includes an enclosure (e.g., enclosures 100 and 300) which encloses circuitry 302, in accordance with some embodiments of the present disclosure. Device 400 includes an enclosure and circuitry 302 arranged within the enclosure. The enclosure, similar to enclosures 100 and 300, includes first outer surface 102, second outer surface 104, and heat sink 106 arranged on the first outer surface 102. In some embodiments, the heat sink 106 includes a plurality of protrusions 108 to provide the device with improved heat dissipation of the enclosure, and a discernible component 110. When circuitry 302 is in operation, heat is generated which transfers to the first outer surface 102 and the second outer surface 104, each of which dissipates the transferred heat to air proximate to device 400.

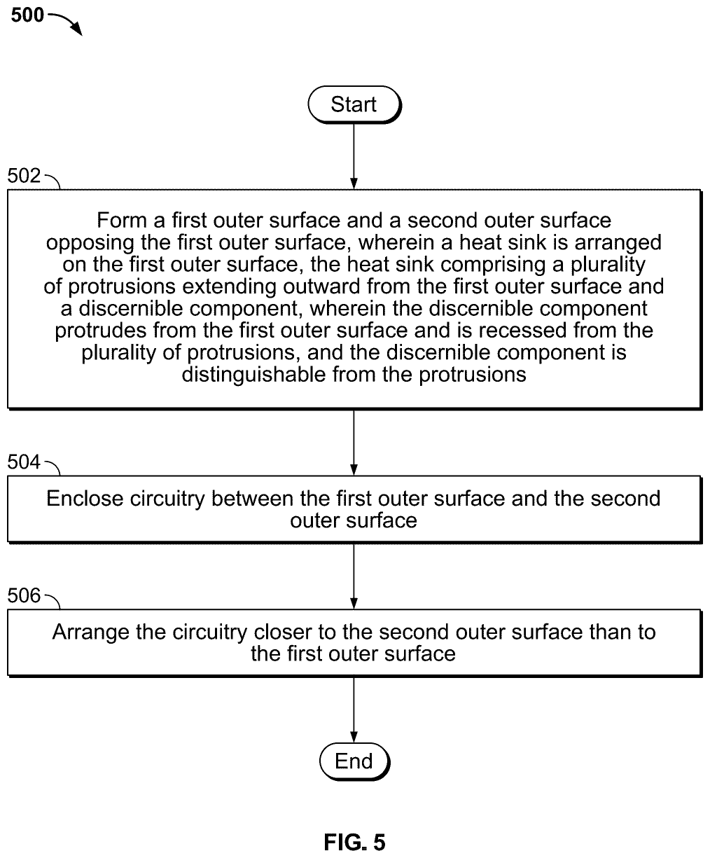

FIG. 5 shows a flowchart of illustrative steps for manufacturing an enclosure with a heatsink, in accordance with some embodiments of the present disclosure. In some embodiments, the referenced enclosure, first outer surface, the second outer surface, the heat sink, plurality of protrusions, discernible component, circuitry, and TIM layers may be implemented as enclosure 100, first outer surface 102, the second outer surface 104, the heat sink 106, plurality of protrusions 108, discernible component 110, circuitry 302, and TIM layers 304 respectively. In some embodiments, the process 500 can be modified by, for example, having steps rearranged, changed, added, and/or removed.

At step 502, form a first outer surface and a second outer surface opposing the first outer surface and a heat sink is arranged on the first outer surface. The heat sink includes a plurality of protrusions extending outward from the first outer surface in order to increase the total surface area from which to dissipate heat generated from the circuitry. The heat sink also includes a discernible component that protrudes from the first outer surface, the discernible component recessed from the plurality of protrusions and is distinguishable from the plurality of protrusions. In some embodiments, the first outer surface, the second outer surface, or both are formed in any one of the following ways: die casting, molding or any other suitable process to form an enclosure of thermally-conductive material (e.g., aluminum). Each of the first outer surface and the second outer surface are thermally-conductive to dissipate heat generated from circuitry which is to be enclosed within the enclosure. In some embodiments, the enclosure is of standardized unit size or standardized dimensions and is to be fitted into/onto a rack or shelf. In such embodiments, the heat sink of the first outer surface is formed by including a recess in the first outer surface such that each of the plurality of protrusions extends outward from the first outer surface. In such embodiments, each protrusion of the plurality of protrusions may only extend as far as the standardized unit size allows.

At step 504, enclose circuitry between the first outer surface and the second outer surface. In some embodiments, the first outer surface and the second outer surface may be joined or physically coupled to form the enclosure in which circuitry is to be enclosed and arranged. The circuitry is to be enclosed within the enclosure for mechanical and electrical protection of circuitry and to improve the thermal dissipation of heat generated by circuitry. The improved thermal dissipation reduces the likelihood of thermal throttling of any electrical components of circuitry. The circuitry may include a printed circuit board (PCB) and at least one electrical component which generates heat during the operation of the circuitry. In some embodiments, the enclosure includes TIM layers which are arranged between the circuitry and each of the first outer surface and the second outer surface, to promote efficient heat transfer from the circuitry to the thermally-conductive enclosure.

At step 506, arrange circuitry closer to the second outer surface than to the first outer surface. In some embodiments, the recess of the first outer surface ensures that less TIM material is used within TIM layers to transfer heat from circuitry to the first outer surface than a first outer surface without a recess in which the protrusions are arranged. In some embodiments, the recess of the first outer surface also enables the heat sink to be formed within a standardized unit size of the enclosure.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. An enclosure comprising:
a first outer surface and a second outer surface opposing the first outer surface; and
a heat sink arranged on the first outer surface, the heat sink comprising:
a plurality of protrusions extending outward from the first outer surface, and
a discernible component, wherein:
the discernible component protrudes from the first outer surface and is recessed from the plurality of protrusions, and
the discernible component is distinguishable from the plurality of protrusions;
wherein:
the enclosure is to enclose circuitry between the first outer surface and the second outer surface, and
the circuitry is arranged closer to the second outer surface than to the first outer surface.

2. The enclosure of claim 1, wherein the first outer surface comprises a recess in which the plurality of protrusions are arranged.

3. The enclosure of claim 2, further comprising a thermal interface material (TIM) layer disposed between the first outer surface and the circuitry, wherein a first amount of TIM disposed between the recess and the circuitry is less than a second amount of TIM disposed between a non-recessed portion of the first outer surface and the circuitry.

4. The enclosure of claim 1, wherein the plurality of protrusions comprises a plurality of fins.

5. The enclosure of claim 1, wherein the plurality of protrusions comprises a plurality of pins.

6. The enclosure of claim 1, wherein each respective protrusion of the plurality of protrusions is parallel to each other protrusion.

7. The enclosure of claim 1, wherein the heat sink and the first outer surface are monolithic.

8. The enclosure of claim 1, wherein the discernible component appears as a recognizable image.

9. A device comprising:
circuitry comprising electrical components; and
an enclosure to enclose the circuitry, the enclosure comprising:
a first outer surface and a second outer surface opposing the first outer surface, wherein the circuitry is enclosed between the first outer surface and the second outer surface and the circuitry is arranged closer to the second outer surface than to the first outer surface; and
a heat sink arranged on the first outer surface, the heat sink comprising:
a plurality of protrusions extending outward from the first outer surface, and
a discernible component, wherein:
the discernible component protrudes from the first outer surface and is recessed from the plurality of protrusions, and
the discernible component is distinguishable from the plurality of protrusions.

10. The device of claim 9, wherein the first outer surface comprises a recess in which the plurality of protrusions are arranged.

11. The device of claim 10, further comprising a thermal interface material (TIM) layer disposed between the first outer surface and the circuitry, wherein a first amount of TIM disposed between the recess and the circuitry is less than a second amount of TIM disposed between a non-recessed portion of the first outer surface and the circuitry.

12. The device of claim 9, wherein the plurality of protrusions comprises a plurality of fins.

13. The device of claim 9, wherein the plurality of protrusions comprises a plurality of pins.

14. The device of claim 9, wherein each respective protrusion of the plurality of protrusions is parallel to each other protrusion.

15. The device of claim 9, wherein the heat sink and the first outer surface are monolithic.

16. The device of claim 9, wherein the discernible component appears as a recognizable image.

17. A method for manufacturing an enclosure, the method comprising:
forming a first outer surface and a second outer surface opposing the first outer surface, wherein a heat sink is arranged on the first outer surface, the heat sink comprising:
a plurality of protrusions extending outward from the first outer surface, and
a discernible component, wherein:
the discernible component protrudes from the first outer surface and is recessed from the plurality of protrusions, and
the discernible component is distinguishable from the plurality of protrusions;
enclosing circuitry between the first outer surface and the second outer surface, and arranging the circuitry closer to the second outer surface than to the first outer surface.

18. The method for manufacturing an enclosure according to claim 17, wherein forming a first outer surface and a second outer surface opposing the first outer surface comprises forming a recess in which the plurality of protrusions are arranged.

19. The method for manufacturing an enclosure according to claim 18, further comprising arranging a thermal interface material (TIM) layer between the first outer surface and the circuitry, wherein a first amount of TIM disposed between the recess and the circuitry is less than a second amount of TIM disposed between a non-recessed portion of the first outer surface and the circuitry.

20. The method for manufacturing an enclosure according to claim 17, wherein forming the first outer surface and the second outer surface opposing the first outer surface comprises casting the first outer surface.

21. The method for manufacturing an enclosure according to claim 17, wherein forming the first outer surface and the second outer surface opposing the first outer surface comprises milling the first outer surface.

22. The method for manufacturing an enclosure according to claim 17, wherein the discernible component appears as a recognizable image.
